(19) United States
(12) Patent Application Publication
(10) Pub. No.: US 2006/0133135 A1
(43) Pub. Date: Jun. 22, 2006

(54) Reducing power in SRAMs while maintaining cell stability

(76) Inventors: Jonathan E. Lachman, Fort Collins, CO (US); Donald R. Weiss, Fort Collins, CO (US); John Wuu, Fort Collins, CO (US); Charles R. Morganti, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/017,981

(22) Filed: Dec. 20, 2004

(51) Int. Cl. G11C 11/00

(52) U.S. Cl. 365/154

(57) ABSTRACT

An SRAM with reduced power consumption comprising N SRAM cells and peripheral circuitry that enables writing and reading any of the N SRAM cells. The number of cells, N, is a whole number. The voltage applied to the N SRAM cells is higher than the voltage applied to the peripheral circuitry.

### FIELD OF THE INVENTION

This invention relates generally to electronic circuits. More particularly, this invention relates to reducing power in SRAMs.

### BACKGROUND OF THE INVENTION

As more electronic circuits are included on a single die, the power dissipated by a single die continues to increase. The power consumption causes the die temperature to increase, degrading the circuits' performance and reliability. In order to keep a single IC (integrated circuit) at a reasonable temperature, many techniques have been used to cool the IC. For example, elaborate cooling fins have been attached to the substrate of ICs. Also, fans have been positioned near a group of IC's to cool them. In some cases, flowing liquids have been used to remove the heat produced by ICs. These solutions can be costly and may require a great deal of space, where space is at a premium. If the power on ICs can be reduced while still achieving higher levels of integration, the cost and volume of a product that use ICs may be reduced.

The number of bits contained on chips containing SRAM, has, on average, quadrupled every three years. As a result, the power that the SRAM consumes has increased. Computer systems can use large numbers of stand-alone SRAM or logic chips with large quantities of embedded SRAM and as a consequence, the power consumed by computer systems, on average, has increased. As the number of SRAM bits on a chip has increased, the voltage applied to these chips has been lowered. Lowering the voltage on a chip containing large quantities of SRAM is one method used to lower the overall system power consumption.

Lowering the voltage applied to SRAM may also degrade the stability of a memory cell. As the stability of a memory cell is degraded, the probability of getting incorrect data from a SRAM memory cell increases. An embodiment of this invention lowers the voltage on all circuits except the voltage on memory cells to decrease the overall power used. The memory cells have a higher voltage than the other circuits on the SRAM chip to maintain the stability of the memory cells.

### BRIEF DESCRIPTION OF THE DRAWINGS

FIG. 1 is a schematic drawing of an SRAM cell. Prior Art

FIG. 2 is a schematic drawing of an SRAM cell using a higher power supply voltage than used in the peripheral circuitry, according to an embodiment of the invention.

FIG. 3 is a schematic drawing of an SRAM using a higher power supply voltage than used in the peripheral circuitry, according to an embodiment of the invention.

### DETAILED DESCRIPTION OF THE PREFERRED EMBODIMENT

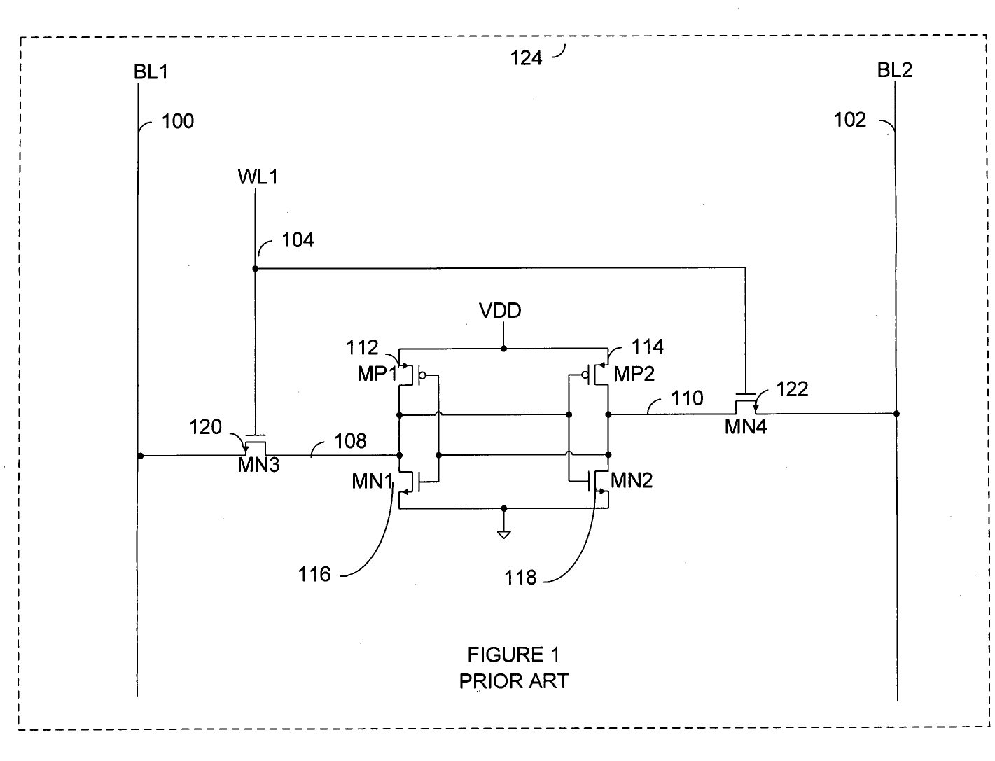

FIG. 1 is a schematic drawing of an SRAM cell, 124. Bitline, BL1, 100 is connected to the source of NFET (N-type Field Effect Transistor), MN3, 120. Bitline, BL2, 102 is connected to the source of NFET, MN4, 122. Wordline, WL1, 104 is connected to the gate of NFET, MN3, 120 and to the gate of NFET, MN4, 122.

The drain, 108, of NFET, MN3, 120 is connected to the drain of PFET (P-type Field Effect Transistor), MP1, 112, the drain of NFET, MN1, 116, the gate of PFET, MP2, 114, and the gate of NFET, MN2, 118.

The drain, 110, of NFET, MN4, 122 is connected to the drain of PFET (P-type Field Effect Transistor), MP2, 114, the drain of NFET, MN2, 118, the gate of PFET, MP1, 112, and the gate of NFET, MN1, 116.

Data may be read from an embodiment of an SRAM cell shown in FIG. 1 as follows. First the wordline, WL1, 104 is charged to a high logical value, charging the gate of NFET, MN3, 120 and the gate of NFET, MN4, 122. Typically, the logical value on node 108 is transferred to bitline 1, BL1, 100 and the logical value on node 110 is transferred to bitline 2, BL2, 102. However, there is a possibility that the charge on bitline, BL1, 100, when WL1, 104, is high, will “flip” the value on node 108 of the SRAM cell, 124, to an opposite value due to charge-sharing. There is also a possibility that the charge on bitline, BL2, 102, when WL1, 104, is high, will “flip” the value on node 110 of the SRAM cell, 124, to an opposite value due to charge-sharing.

The sizes of NFET, MN1, 116, NFET MN2, 118, NFET MN3, 120, NFET MN4, 122, PFET MP1, 112, and PFET MP2, 114, among other reasons, are chosen to provide enough drive strength to hold the drains of NFETs MN3, 120, and MN4, 122 in their present state preventing the SRAM cell, 124, from flipping when data is read. In addition, the sizes of these six FETs are chosen to simultaneously optimize for the read access time of the SRAM cell, 124.

Data may be written to an embodiment of an SRAM cell shown in FIG. 1 by first driving WL1, 104 to a high logical value. After driving WL1, 104 to a high logical value, BL1, 100 is driven to either a high or low logical value at the same time BL2, 102, is driven to the opposite value of the value on BL1, 100. Typically, this causes the SRAM cell, 124, to flip to the logical value imposed by BL1, 100 and BL2, 102. After the SRAM cell, 124, is written, WL1, 104, is discharged to a low logical value.

The power supply voltage, VDD, used in this example for the SRAM cell, 124, is the same power supply voltage, VDD, used for all the peripheral circuitry on the SRAM.

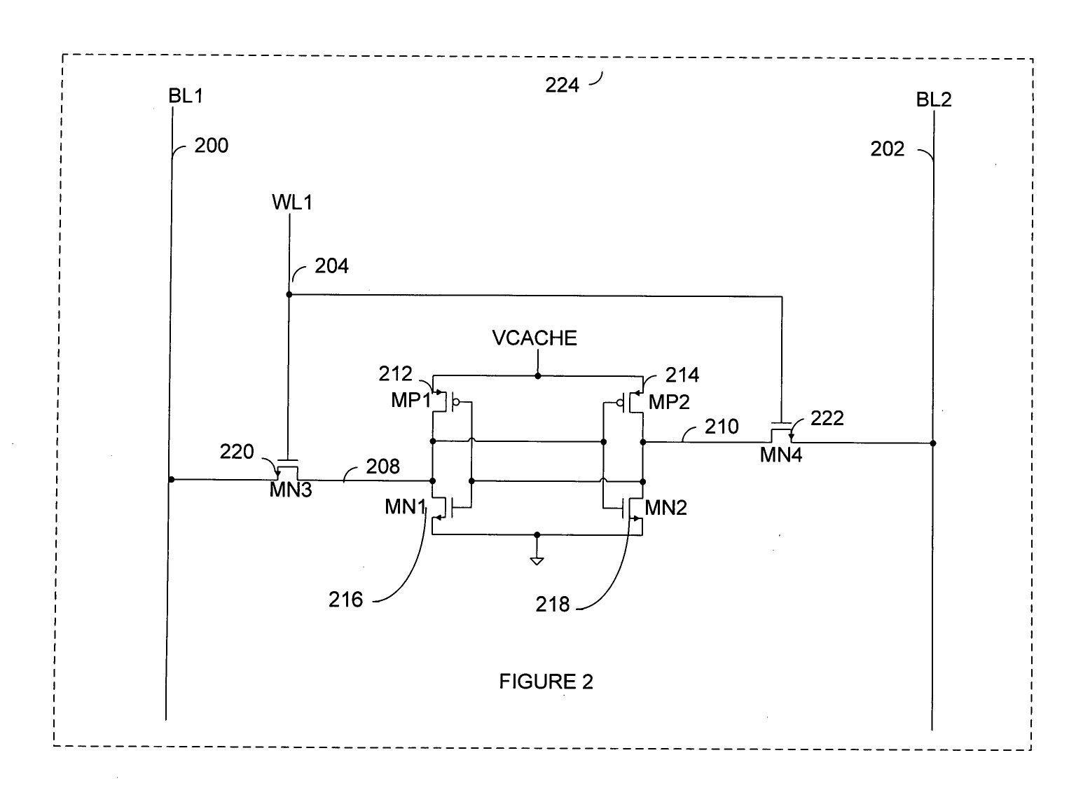

FIG. 2 is a schematic drawing of an SRAM cell, 224, using a higher power supply voltage, VCACHE, than the power supply voltage, VDD, used in the peripheral circuitry. Bitline, BL1, 200 is connected to the source of NFET (N-type Field Effect Transistor), MN3, 220. Bitline, BL2, 202 is connected to the source of NFET, MN4, 222. Wordline, WL1, 204 is connected to the gate of NFET, MN3, 220 and to the gate of NFET, MN4, 222.

The drain, 208, of NFET, MN3, 220 is connected to the drain of PFET (P-type Field Effect Transistor), MP1, 212, the drain of NFET, MN1, 216, the gate of PFET, MP2, 214, and the gate of NFET, MN2, 218.

The drain, 210, of NFET, MN4, 222 is connected to the drain of PFET (P-type Field Effect Transistor), MP2, 214, the drain of NFET, MN2, 218, the gate of PFET, MP1, 212, and the gate of NFET, MN1, 216.

Data may be read from an embodiment of an SRAM cell shown in FIG. 2 as follows. First, wordline, WL1, 204 is charged to a high logical value, charging the gate of NFET, MN3, 220 and the gate of NFET, MN4, 222. Typically, the logical value on node 208 is transferred to bitline 1, BL1, 200 and the logical value on node 210 is transferred to bitline 2, BL2, 202. However, there is a possibility that the charge on bitline, BL1, 200, when WL1, 204, is high, will “flip” the value on node 208 of the SRAM cell, 224, to an opposite value due to charge-sharing. There is also a possibility that the charge on bitline, BL2, 202, when WL1, 204, is high, will “flip” the value on node 210 of the SRAM cell, 224, to an opposite value due to charge-sharing.

The sizes of NFET, MN1, 216, NFET MN2, 218, NFET MN3, 220, NFET MN4, 222, PFET MP1, 212, and PFET MP2, 214, among other reasons, are chosen to provide enough drive strength to hold the drains of NFETs MN3, 220, and MN4, 222 in their present state preventing the SRAM cell, 224, from flipping when data is read. In addition, the sizes of these six FETs are chosen to simultaneously optimize for the read access time of the SRAM cell, 224.

Data may be written to an embodiment of an SRAM cell shown in FIG. 2 by first driving WL1, 204, to a high value. After driving WL1, 204, to a high logical value, BL1, 200 is driven to either a high or low logical value at the same time BL2, 202, is driven to the opposite value of the value on BL1, 200. Typically, this causes the SRAM cell, 224, to flip to the logical value imposed by BL1, 200 and BL2, 202. After the SRAM cell, 224, is written, WL1, 204, is discharged to a low logical value.

The power supply voltage, VCACHE, used in this example for the SRAM cell, 224, is higher than the power supply voltage, VDD, used for all the peripheral circuitry on the SRAM. The voltage provided to the wordline, WL1, 204, must be high enough to ensure that the SRAM cell, 224, can be read and written. The voltage provided to the bitlines, BL1, 200, and BL2, 202, must be high enough to ensure that the SRAM cell, 224, can remain stable when read, and be read and written at speeds required by the circuit.

In this example, because the peripheral circuitry has a lower power supply voltage, VDD, than the power supply voltage for the SRAM cells, VCACHE, power can be saved. At the same time, since the power supply voltage, VCACHE, has a higher voltage than the peripheral circuitry power supply, VDD, the stability and performance of the SRAM cell, 224, is improved.

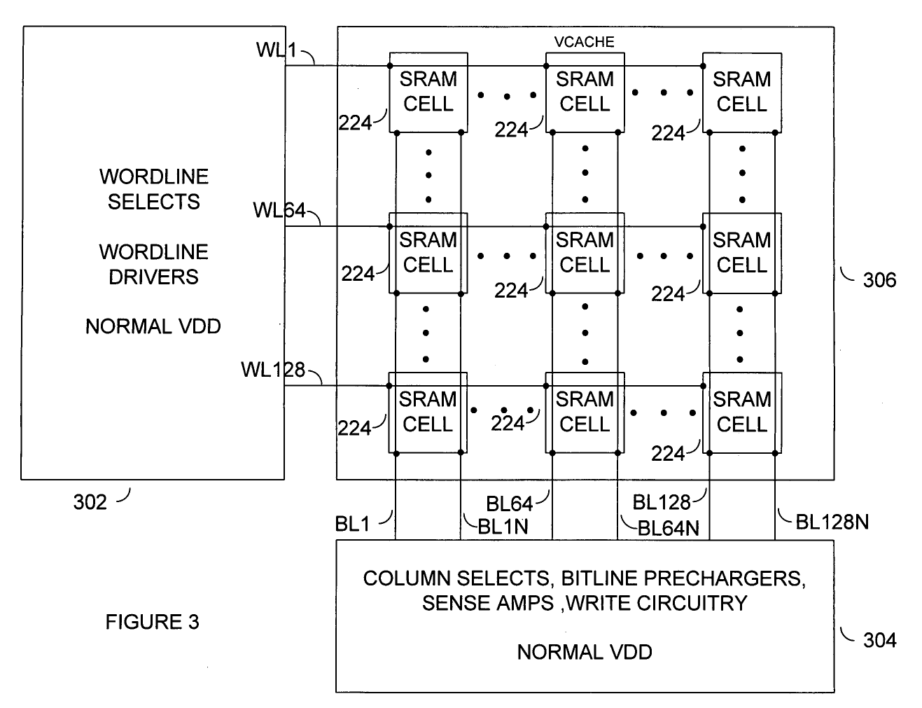

FIG. 3 is a schematic drawing of an SRAM using a higher power supply voltage, VCACHE, in the SRAM array, 306, than the power supply, VDD used for the peripheral circuitry, 302 and 304. Circuitry, 302, includes wordline selects, and wordline drivers connected to VDD. The wordline drivers drive the wordlines WL1-WL128 in this example. The voltage on the wordlines, WL1-WL128, should be high enough to write and read the SRAM cells, 224.

Other circuitry, 304, including column selects, bitline prechargers, sense amps, and write circuitry, is connected to VDD. Bitline prechargers charge bitline pairs, BL1-BL1N through BL128-BL128N. The bitline pairs, BL1-BL1N through BL128-BL128N, should be charged to a high enough voltage that allows the SRAM cells, 224, to be stable when read.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) An SRAM with reduced power consumption comprising:
a) N SRAM cells;
b) peripheral circuitry that enables writing and reading any of the N SRAM cells;
c) wherein N is a whole number;
d) wherein a voltage applied to the N SRAM cells is higher than a voltage applied to the peripheral circuitry.

2) The SRAM as in claim 1 wherein the SRAM is a stand-alone SRAM.

3) The SRAM as in claim 1 wherein the SRAM is part of another IC.

4) The SRAM as in claim 3 wherein the IC is a microprocessor.

5) The SRAM as in claim 3 wherein the IC is a DRAM.

6) The SRAM as in claim 1 wherein the peripheral circuitry comprises:
a) wordline drivers;
b) word selects;
c) column selects;
d) bitline prechargers;
e) sense amps and;
f) write circuitry.

7) The SRAM as in claim 6 wherein a voltage generated on a wordline by any of the wordline drivers is sufficient to write a group of the SRAM cells.

8) The SRAM as in claim 6 wherein a voltage generated on a bitline pair by any of the write circuitry is sufficient to write a group of the SRAM cells.

9) The SRAM as in claim 6 wherein a voltage generated on a wordline by any of the wordline drivers is sufficient to read a group of the SRAM cells.

10) The SRAM as in claim 6 wherein a voltage generated on a bitline pair by any of the bitline prechargers is sufficient for stable SRAM cell operation during a read.

11) A method of manufacturing an SRAM with reduced power consumption comprising:
a) fabricating N SRAM cells;
b) fabricating peripheral circuitry that enables writing and reading any of the N SRAM cells;
c) wherein N is a whole number;
d) wherein a voltage applied to the N SRAM cells is higher than a voltage applied to the peripheral circuitry.

12) The method as in claim 11 wherein the SRAM is a stand-alone SRAM.

13) The method as in claim 11 wherein the SRAM is part of another IC.

14) The method as in claim 13 wherein the IC is a microprocessor.

15) The method as in claim 13 wherein the IC is a DRAM.

16) The method as in claim 11 wherein the peripheral circuitry comprises:
a) wordline drivers;
b) wordline selects;
c) column selects;
d) bitline prechargers;
e) sense amps and;
f) write circuitry.

17) The method as in claim 16 wherein a voltage generated on a wordline by any of the wordline drivers is sufficient to write a group of the SRAM cells.

18) The method as in claim 16 wherein a voltage generated on a bitline pair by any of the write circuitry is sufficient to write a group of the SRAM cells.

19) The method as in claim 16 wherein a voltage generated on a wordline by any of the wordline drivers is sufficient to read a group of the SRAM cells.

20) The method as in claim 16 wherein a voltage generated on a bitline pair by any of the bitline prechargers is sufficient for stable SRAM cell operation during a read.
